(19) United States
(12) Patent Application Publication
(10) Pub. No.: US 2006/0124593 A1
(43) Pub. Date: Jun. 15, 2006

(54) Colloidal silica based chemical mechanical polishing slurry

(75) Inventors: Gert R.M. Moyaerts, Phoenix, AZ (US); Ken A. Delbridge, Chandler, AZ (US); Nichole R. Koontz, Mesa, AZ (US); Saeed H. Mohseni, Sylvania, OH (US); Gerome J. Sayles, Adrian, MI (US); Deepak Mahulikar, Madison, CT (US)

Correspondence Address: OHLANDT, GREELEY, RUGGIERO & PERLE, LLP, ONE LANDMARK SQUARE, 10TH FLOOR, STAMFORD, CT, 06901, US

(73) Assignee: Planar Solutions, LLC

(21) Appl. No.: 11/141,162

(22) Filed: May 31, 2005

Related U.S. Application Data
(60) Provisional application No. 60/635,534, filed on Dec. 13, 2004.

(51) Int. Cl. C09K 3/14; C09G 1/02; C09K 13/00; H01L 21/461; B44C 1/22; H01L 21/302; C09C 1/68; C23F 1/00; B24D 3/02

(52) U.S. Cl. 216/88; 51/307; 51/308; 51/309; 106/3; 252/79.1; 216/89; 438/692

(57) ABSTRACT

A composition for chemical mechanical polishing a surface of a substrate having a plurality of ultra high purity sol gel processed colloidal silica particles for chemical mechanical polishing having alkali metals Li, Na, K, Rb, Cs, Fr and a combination thereof, at a total alkali concentration of about 300 ppb or less, with the proviso that the concentration of Na, if present, is less than 200 ppb; and a medium for suspending the particles is provided. Also, provided are methods of chemical mechanical polishing which included a step of contacting a substrate and a composition according to the present invention. The contacting is carried out at a temperature and for a period of time sufficient to planarize the substrate.

### BACKGROUND OF THE INVENTION

This application claims priority from Provisional Application Ser. No. 60/635,534, filed on Dec. 13, 2004.

### FIELD OF THE INVENTION

The present invention relates to a colloidal silica-based composition and a method for chemical mechanical polishing “CMP” of a substrate layer. More particularly, the invention relates to an ultra high purity sol gel processed colloidal silica based composition and ultra high purity sol gel processed colloidal silica particles with a low alkali metal concentration whose chemical polishing properties can be controlled by varying the particle's characteristics including the size, shape, concentration, and surface area.

### DESCRIPTION OF RELATED ART

Polishing compositions for use in CMP are well known in the art. For example, such compositions or slurries can be used for the removal of different layers from substrates such as high-density integrated circuits. The circuits are typically formed on substrates such as silicon wafers by the sequential deposition of conductive, semiconductive or insulating layers. As the layers are sequentially deposited and etched, the uppermost or outer surface of the substrate becomes successively less planar.

Excessive degrees of surface nonplanarity affect the quality of the substrate surface which may, in some cases, limit the formation of desired high resolution semiconductor feature patterns during the fabrication process. CMP compositions contribute to the planariziation and removal of excess surface metals from substrates or multi-layer semiconductor devices. At each level of substrate manufacturing, CMP compositions or slurries can be used to polish the substrate surface in preparation for a subsequent layer.

CMP compositions contain abrasive materials such as silica or alumina suspended in an aqueous medium. The abrasives are typically formed using two different methods, which result in fumed and colloidal abrasives. For example, the fumed silica particles can be made from a SiCl₄ burning process, whereas most colloidal silica is solution grown or made from a sol gel process using a chemical reaction with a Si metal.

Depending on the % solids and type of particles and for the same concentration, fumed particles, in general, present a higher surface removal rate than colloidal particles due to their sharp edged features. For similar reasons, the defect density using fumed particles tends to be higher, and less adjustable. For example, very high coral or black diamond (dielectric) removal rates result in undesirable effects that may interfere with the integrated circuit manufacture process and subsequent performance. In contrast, colloidal particles have a more uniform particle-size distribution and minimize surface defects resulting in improved surface topography.

The use of slurries for CMP of copper-containing layers is also a well-established commercialized process for 130 nm technology nodes and beyond. Manufacturers including Intel, Texas Instruments, and IBM, have implemented the process in High Volume Manufacturing (HVM). Typically, the process uses a two-step-polishing regime. In the first step, a bulk of the Cu is removed using a high Cu removal-rate slurry with high selectivity for Ta. In the second step, the barrier (Ta or TaN) is removed resulting in good topography and low defectivity. As used herein, defectivity refers to the level of surface defects such as macro or micro scratches on a substrate during CMP.

To achieve the desired topography, the barrier-removal slurry can use a high or low selectivity composition such as that described in U.S. Pat. No. 6,083,840 to Mravic et al. The composition uses an abrasive, an oxidizer, and a carboxylic acid with certain optional additives for optimal topography. An example of such a slurry is Cu10K-2, made by Planar Solutions as described in published U.S. Patent Publication No. 20030064671 to Deepak et al. The slurry uses fumed silica as an abrasive for 130 nm and 90 nm barrier polish applications. These applications use Tetraethylothosilicate (TEOS) or Fluorinated Silicate Glass (FSG) as dielectric materials.

However, these conventional 130 nm slurries, i.e., Cu10K-2, generally are not adequate for 65 nm polishing, especially from defectivity perspective. The next generation wafers (65 nm and some 90 nm technology nodes) that use Carbon Doped Oxides (CDOs) and other Low-k materials as the interlayer Dielectrics (ILDs), present unique challenges because they are susceptible to significant substrate defectivity in comparison to TEOS composites. The narrower lines associated with the more recent generation provide that smaller substrate micro-scratches and particles can become critical or killer defects. Second, the substrates have a finer geometry which combined with other factors such as low k, Cu, and Ta, appears to cause a more particularized type of killer defect characterized by a “FANG” or “tiger teeth” profile, which results in leakage current and yield loss.

Moreover, wafers with CDOs have relatively non-uniform carbon doping, which produces different flat film and patterned wafer CDO removal rates whereby the loss observed on patterned wafers interferes with integration. The non-uniformity of interlayer dielectric (ILD) loss between different arrays is also undesirable during manufacturing. As used herein, ILD loss refers to how much insulating material is consumed during polishing (Erosion) and can be controlled by adjusting the polish time.

Adhesion or delamination interactions between Copper-Doped Oxides and Cu tend to require a lower down-force polish (DF) during the CMP process, which may jeopardize throughput for future technology nodes that use thinner barriers and wafers.

It is therefore an object of the present invention is to provide a colloidal manufactured abrasive for CMP that provides the desired surface planarization, including high material removal rate, while minimizing the surface defects on substrates or semiconductor wafer surfaces.

### SUMMARY OF THE INVENTION

The present invention provides a composition for chemical mechanical polishing a surface of a substrate having a plurality of ultra high purity sol gel processed colloidal silica particles for chemical mechanical polishing having alkali metals selected from Li, Na, K, Rb, Cs, Fr and a combination thereof, at a total alkali concentration of about 300 ppb or less, with the proviso that the concentration of Na, if present, is less than about 200 ppb; and a medium for suspending the particles. The composition can further include an alkoxylated surfactant, a carboxylic acid, an oxidizer, and a corrosion inhibitor.

The present invention further provides a composition for polishing a metal-containing composite having a plurality of sol gel silica particles wherein the particles have a primary particle size from about 10 nm to about 50 nm and a secondary particle size from about 20 nm to about 150 nm, an alkoxylated surfactant having a concentration from about 10 ppm to about 1000 ppm, and a medium for suspending the sol gel silica particles.

Also provided is a method of polishing a metal-containing composite. The method includes the step of: contacting the metal-containing composite and a plurality of sol gel silica particles having a primary particle size from about 10 nm to about 50 nm and a secondary IS particle size from about 20 nm to about 150 nm; and an alkoxylated surfactant having a concentration from about 10 ppm to about 1000 ppm; and a medium for suspending the sol gel silica particles; wherein the contacting is carried out at a temperature and for a period of time sufficient to planarize the metal-containing composite.

In another embodiment, a method of chemical mechanical polishing of a substrate is provided. The method includes the step of: contacting the substrate and a plurality of ultra high purity sol gel processed colloidal silica particles for chemical mechanical polishing having alkali metals selected from Li, Na, K, Rb, Cs, Fr and a combination thereof, at a total alkali concentration of about 300 ppb or less, with the proviso that the concentration of Na, if present, is less than 200 ppb; and a medium for suspending the particles; wherein the contacting is carried out at a temperature and for a period of time sufficient to planarize the substrate.

### BRIEF DESCRIPTION OF THE DRAWINGS

FIG. 1 shows a Transmission Electron Microscopic (TEM) image of Aggregated-shape colloidal particles.

FIG. 2 shows a Transmission Electron Microscopic (TEM) image of a single Spherical-shape particle.

FIG. 3 shows another Transmission Electron Microscopic (TEM) image of Spherical-shape colloidal particles.

FIG. 4 shows a Transmission Electron Microscopic (TEM) image of Cocoon-shape colloidal particles.

FIG. 5 shows a Transmission Electron Microscopic (TEM) image of Aggregated-shape colloidal particles with a larger particle size.

FIG. 6 shows an example of comparative Cu, Ta, Coral, and TEOS removal rates in the presence of selected surfacants, for example, Surfacant A and Surfacant B.

FIG. 7 shows a response curve for removal rate vs. Surfacant B concentration.

FIG. 8 shows a comparison of defectivity ranges for fumed silica slurries such as Cu10K-SPF, versus sol gel colloidal silica containing slurries.

FIG. 9 shows a Large Particle Count (LPC) for Sol Gel based slurry containing a surfactant after being filtered with four different filter schemes.

FIG. 10 shows a comparison of removal rates using Cu10K-SPF and advanced Barrier Slurry ER10600-G.

FIG. 11 shows a comparison of removal rates of two slurry formulations GS1422-13B without surfactant (Control), and GS1422-13A with surfactant.

FIG. 12 shows a pattern Dishing comparison for different sol gel particles and loading.

FIG. 13 shows Erosion for different Sol Gel Particles

FIG. 14 shows Interlayer Dielectrics (ILD) loss for ER 1600-platform slurries.

FIG. 15 shows the Effect of pH on Dishing.

FIG. 16 shows the Effect of pH on Erosion.

### DETAILED DESCRIPTION OF THE INVENTION

The present invention provides a plurality of ultra high purity sol gel processed colloidal silica particles for chemical mechanical polishing with alkali metals selected from Li, Na, K, Rb, Cs and Fr. The concentration of Na, if present, is less than 200 ppb and the silica particles have a low concentration of impurities. For example, the particles have an alkali metal concentration of about 300 ppb or less with preferred ranges of about 250 ppb, 200 ppb, 150 ppb, and 100 ppb or less. The preferred alkali metals include Li, Na, K, Rb, Cs, Fr, and a mixture thereof.

The particles have a low level of heavy alkali metals with a concentration about 100 ppb or less. The preferred incremental ranges are about 75 ppb and 50 ppb or the heavy alkali metals include Rb, Cs, Fr, or any mixture thereof.

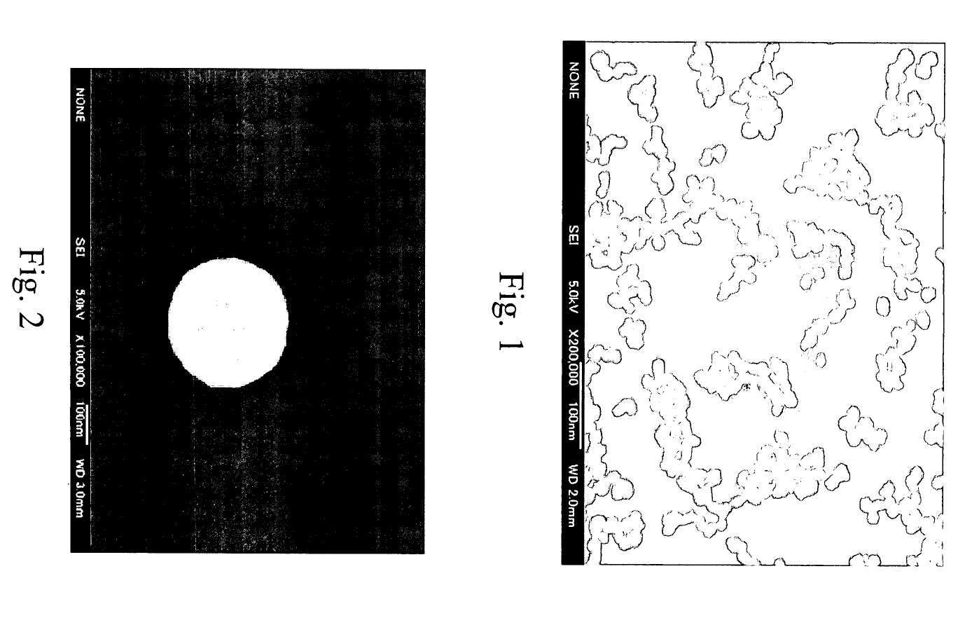

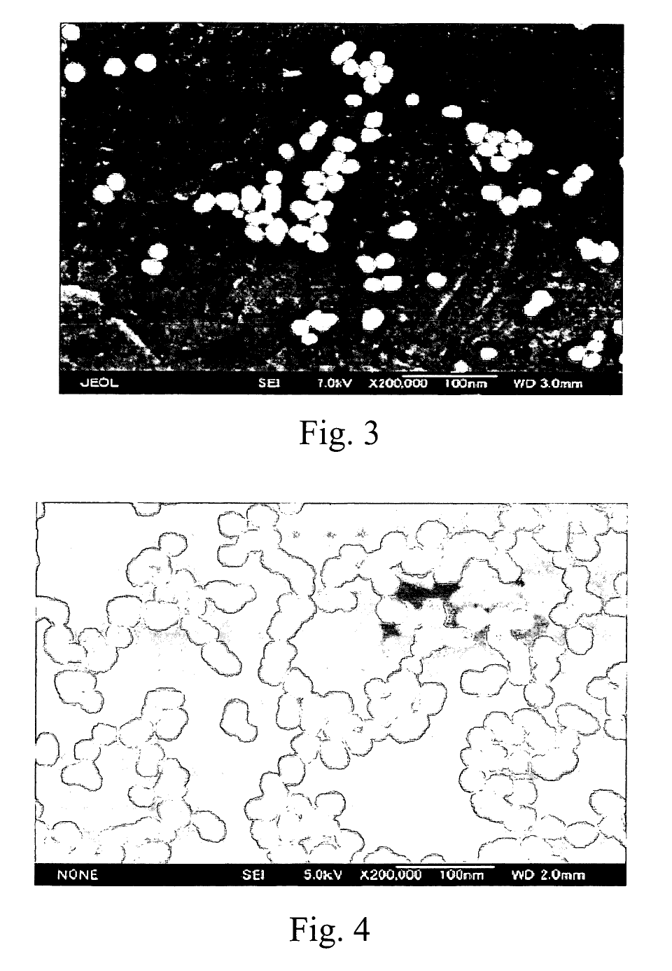

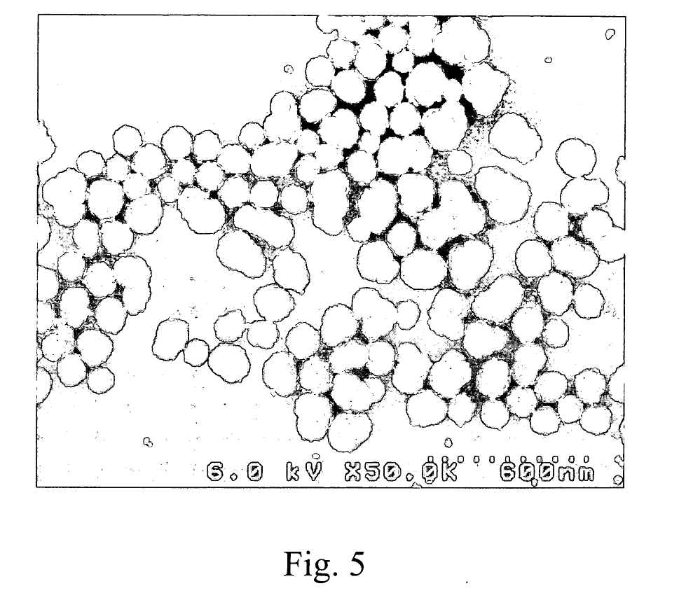

In a preferred embodiment, the silica particles have a mean particle size from about 60 nm to about 200 nm. To achieve the desired planarization, the particle shape can be varied. For example, FIG. 1 and FIG. 5 depict aggregated-shape particles, FIG. 2 depicts a single spherical-shape particle, FIG. 3 depicts spherically shaped particles, and FIG. 4 depicts cocoon-shape particles.

The selected-shape particles can be suspended in a variety of mediums to produce a polishing composition. For example, the particles may proportionately include a greater concentration of larger size or primary particles, with a lesser concentration of smaller size or secondary particles. The result of this size variation is an improved removal rate of surface impurities and controlled surface topography not provided by conventional polishes.

In yet another embodiment, the composition for polishing a metal-containing composite includes a plurality of sol gel silica particles wherein the particles have a primary particle size from about 10 nm to about 50 nm and a secondary particle size from about 20 nm to about 150 nm; and an alkoxylated surfactant having a concentration from about 10 ppm to about 1000 ppm; and a medium for suspending the sol gel silica particles. The wherein the medium has a pH of about 9.0 to about 11.

The composition can further includes an additive selected from a carboxylic acid or a mixture of carboxylic acids present in a concentration of about 0.01 wt. % to about 0.9 wt. %; an oxidizer, present in a concentration of about 10 ppm to about 2,500 ppm; and a corrosion inhibitor, present in the range of about 10 ppm to about 1000 ppm.

In a preferred embodiment the primary particles, with a particle size from about 30 nm to about 100 nm, include at least 50% of the composition, and the secondary particles, with a particle size from about 38 to about 200 nm, include at least 0.5% to 49% of the remaining composition. The mediums for suspension further include, but are not limited to, water, an organic solvent, and mixtures thereof.

The resulting composition can also be in the form of an emulsion, a colloidal suspension, a solution, and a slurry in which the particles are uniformly dispersed and are stable both at basic and acidic pH and includes a Surfactant. In a preferred embodiment, a cationic, is anionic, non-ionic, amphoteric surfactants or a mixture, more preferably a non ionic surfactant is used to significantly reduce surface removal rates at or above 50 PPM. Preferably an upper limit of about 1000 PPM because at this level, organic residue, defectivity is observed on the wafer surfaces. Therefore, a non-ionic surfacant is preferred because of its inert reactivity to other films like Cu and Ta.

The particles in the composition also have a low level of trace metals and alkali metals such as Li, Na, K, Rb, Cs, and Fr. The particles have a low level of heavy alkali metals such as Rb, Cs, and Fr and have a mean particle size from about 60 nm to about 200 nm. An alkali metal concentration below 300 ppb is preferred with a primary particle concentration within the composition of at least 50% and a secondary particle concentration of about 0.5% to 49%.

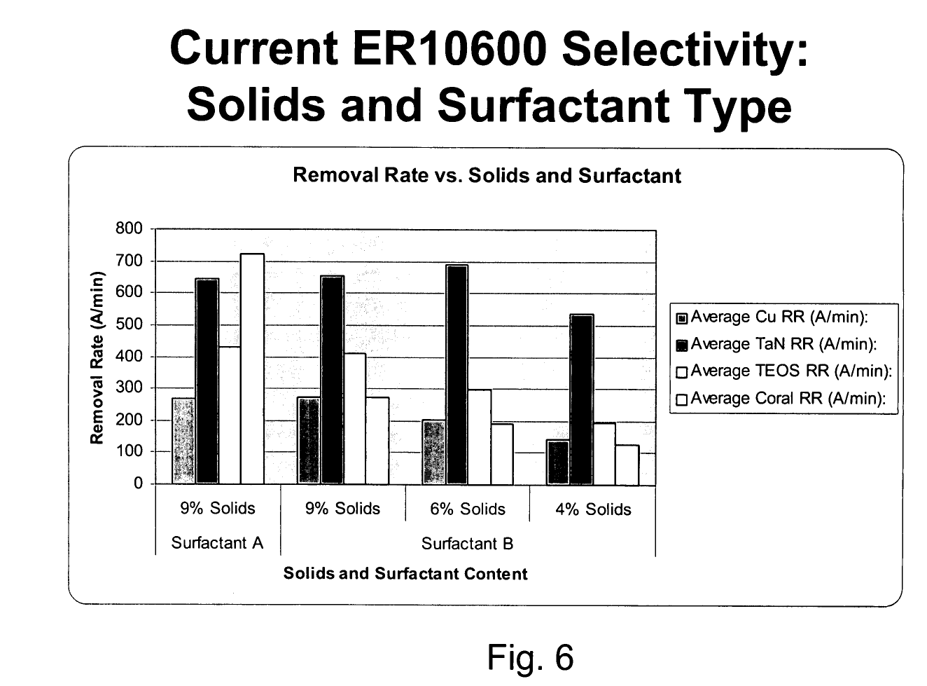

Preferably, silica particles of a surface area from about 80 m²/g to about 90 m²/g, include from about 19 wt. % to 24 wt. % of the total weight of the composition and the medium includes about 81 wt. % to 86 wt. % of the composition. As described above, the medium can be water, an organic solvent or a mixture thereof, which can result in an emulsion, collodial suspension, or slurry. For example, FIG. 6 shows a direct relationship between substrate (Cu, TaN, TEOS, and Coral) removal rates and concentration of solids, fumed or colloidal silica particles. The effects of the surfactant include a reduction in polishing friction as discussed below.

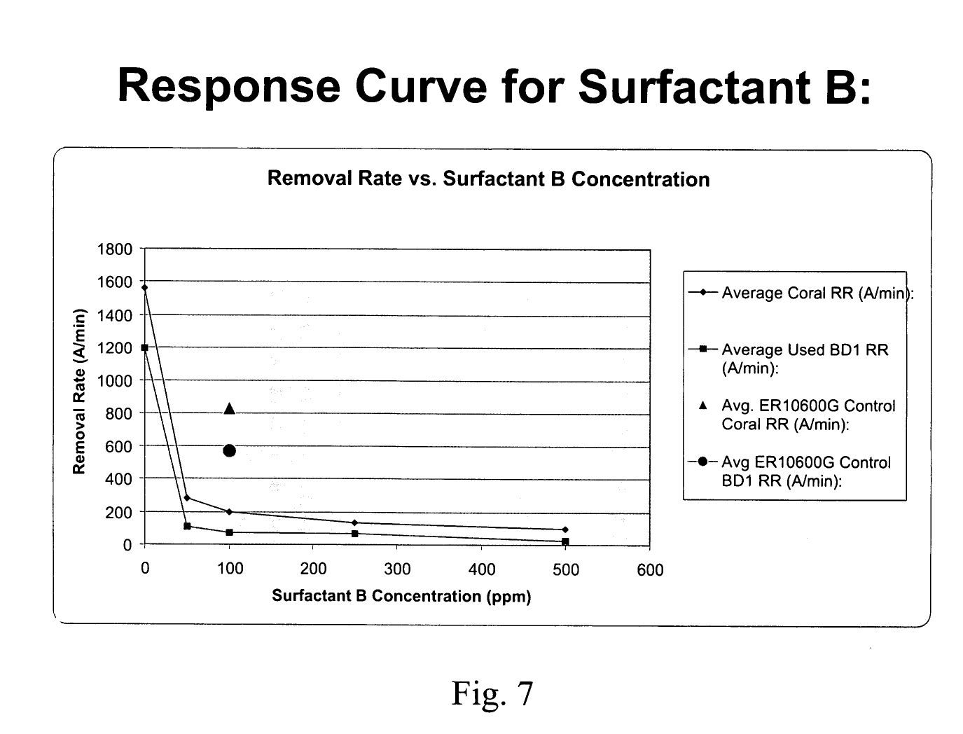

In another embodiment, a composition for polishing a metal-containing composite is provided and includes a plurality of sol gel silica particles wherein the particles have a primary particle size from about 10 nm to about 50 nm and a secondary particle size from about 20 nm to about 150 nm; an alkoxylated surfactant having a concentration from about 10 ppm to about 1000 ppm; and a medium for suspending the sol gel silica particles. A surfactant, as shown in FIG. 7, lowers the removal rate by further reducing frictional forces on the substrate surface.

The pH of the composition is maintained in the range of about 9.0 to about 11, and the composition can further include an additive selected from a carboxylic acid, present in a concentration of about 0.01 wt. % to about 0.9 wt. %; an oxidizer, present in a concentration of about 10 ppm to about 2,500 ppm; and a corrosion inhibitor, present in the range of about 10 ppm to about 1000 ppm.

In another embodiment, the present invention provides a method of chemical mechanical polishing a substrate. The method has the step of contacting the substrate and a composition having a plurality of ultra high purity sol gel processed colloidal silica particles having at least one alkali metal selected from Li, Na, K, Rb, Cs, Fr and a combination thereof, at a total alkali concentration of about 300 ppb or less, with the proviso that the concentration of Na, if present, is about 200 ppb or less; and a medium for suspending the colloidal silica sol gel processed silica particles. The contacting step is carried out at a temperature and for a period of time sufficient to planarize the substrate.

The method of chemical mechanical polishing according to the present invention can employ any of the above described preferred embodiments of the sol gel processed colloidal particles, including the compositions wherein the particles have an appropriately selected mean particle size of primary and secondary particles for a desired removal rate of the material and topography.

In yet another embodiment, a method for polishing a metal-containing composite is provided. The method can use a composition that includes a plurality of sol gel silica particles wherein the particles have a primary particle size from about 10 nm to about 50 nm and a secondary particle size from about 20 nm to about 150 nm; an alkoxylated surfactant, having a concentration from about 10 ppm to about 1000 ppm; and a medium for suspending the sol gel silica particles.

The pH of the solution used in the method is maintained in the range of about 9.0 to about 11, and can further include an additive selected from a carboxylic acid, present in a concentration of about 0.01 wt. % to about 0.9 wt. %; an oxidizer, present in a concentration of about 10 ppm to about 2,500 ppm; and a corrosion inhibitor, present in the range of about 10 ppm to about 1000 ppm.

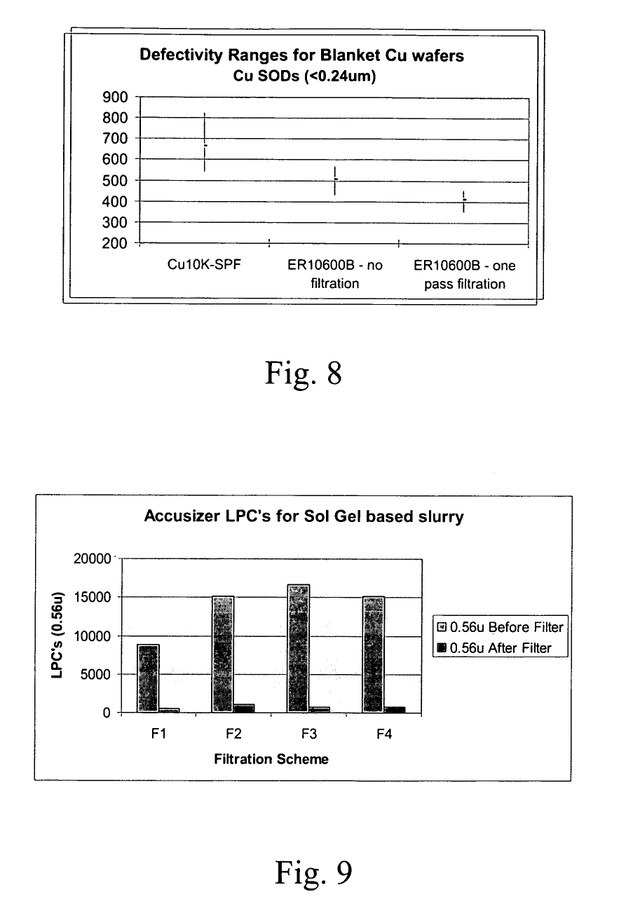

Optimal topography along with low defectivity, minimal Fang defects, and an increase in removal rates can be achieved at a predetermined combination of abrasive concentration, particle size distribution, and chemistry. For example, while fumed particles can be used with the present invention, sol gel based colloidal silica particles are preferred because of their overall purity, size and variable shapes. As shown in FIG. 8, sol gel colloidal silica slurries “ER” slurries with or without filtration provide improved and significantly lower defectivity compared to fumed silica-based Cu10K-SPF. Defectivity is further reduced with Filtration. Irrespective of the filtration scheme used, sol gel based slurries are very easily filtered which enables an end user or skilled artisan to use a broad range of Point of Use filters (POU) with a much longer lifetime. This results in low large particle counts (LPCs) FIG. 9.

As described above, primary particle sizes can range from about 10 to 100 nm, and particle shapes can range from spherical, cocoon to aggregate. For desired polishing, these characteristics can be varied to obtain a critical size/shape combination that provides optimized performance. This additional variation in particle characteristics is often necessary to adjust for the particle manufacturing process that requires Na based materials that contain a large amount of trace metals. Without such adjustment, these impurities can compromise device electrical yield and increase wafer defectivty.

For example, the selection of a high mean particle size (MPS) sol gel silica (190 nm) with a low percentage of solids, e.g., 3%, yields higher Ta removal rates and lower defectivity than the Cu10K-2 slurry. The large MPS size, however, can cause severe settling and phase separation after some time, i.e., one week.

Alternatively, selecting a small particle-size dispersion made with 20 nm-size colloidal silica provides low defectivity and good stability, but to achieve the same removal rates as the 190 nm particle slurry, substantially more composition is required. An intermediate selection of MPS dispersion made using 60 nm-size colloidal silica is therefore desired, and provides good all round performance.

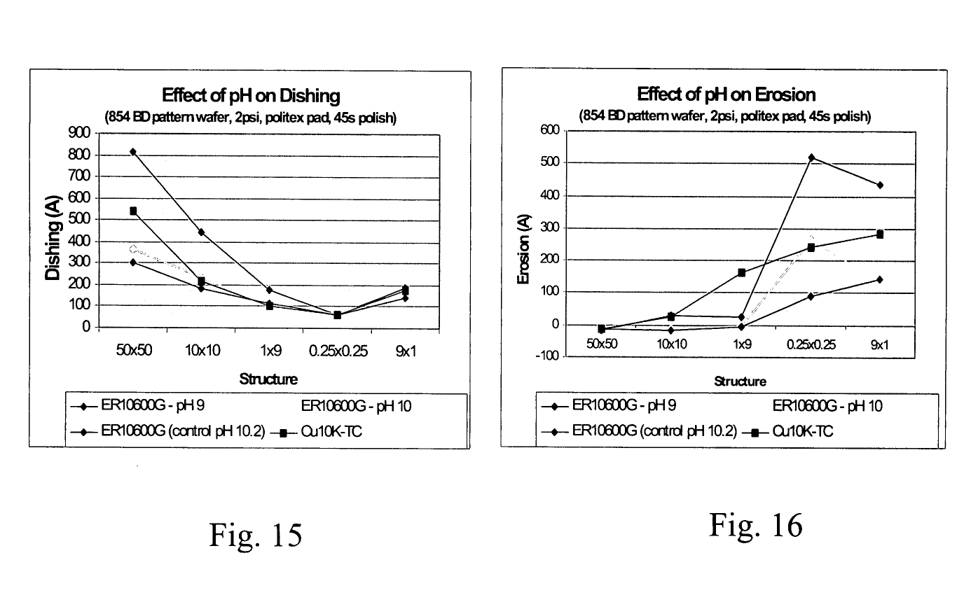

As described above, the dispersion can contain a surfactant that adjusts the slurry properties for desired topography. Data for slurries using the same chemistry (oxidizer, carboxylic acid, a corrosion inhibitor, and a surfactant) for different pH values are shown in FIG. 16, which compares the effect of pH on Erosion. FIG. 15 shows the effect of pH on Dishing. The surfactant stabilizes the slurry over a wide pH range so that polishing rates can be maintained, or even increased to produce a significantly improved surface finish. For optimal topography the pH is preferably controlled between 9-11 with the addition of the surfactant.

Furthermore, surfactant-containing slurries are more easily filtered than those without. Filtration of slurries is often necessary to reduce oversized or defect-causing particles from the polishing slurry at the Point of Use (POU). Also, as shown in FIG. 8, sol gel colloidal silica slurries (ER 10600B-no filtration, and ER1060B-one pass filtration), have significantly lower defectivity compared to fumed silica based silica slurries (Cu10K-SPF). This characteristic is true for Sol Gel based slurries even without filtration. The addition of a surfactant, as shown in FIG. 9, results in lower LPC (Large Particle Counts) thereby reducing the need for additional POU filters.

The wetability of the slurry is also improved by the addition of a surfacatant. Slurries that contain a surfactant have smaller wafer contact angles than those without the surfactant, which indicates that the use of the surfactant improves resist-surface wetting. Furthermore, high surfactant loading produces a smaller contact angle than low surfactant loading, which means that high loading causes the wafer surface to become wet faster.

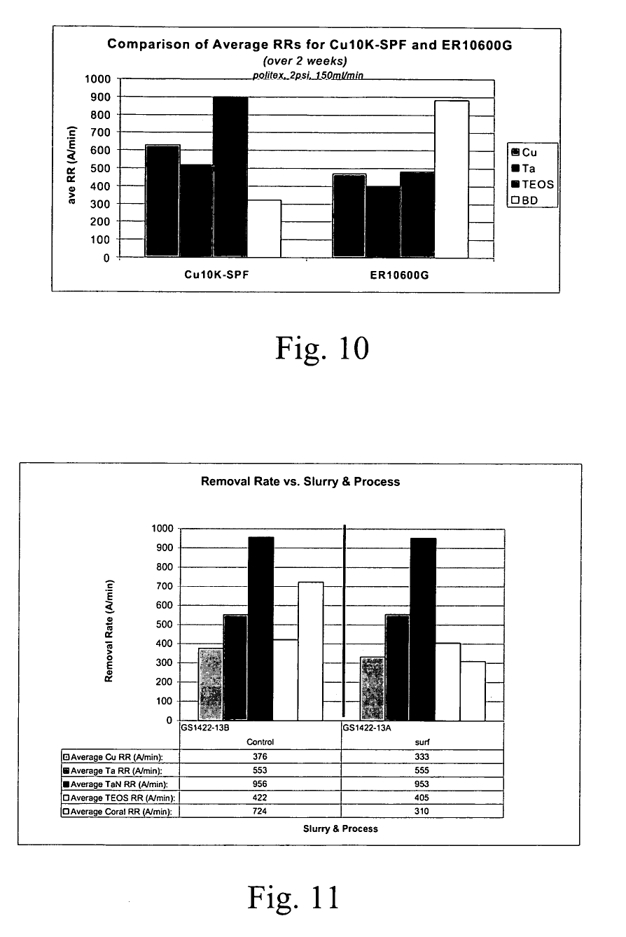

In a preferred embodiment, a surfactant containing a sol gel slurry (ER10600-G) is used to polish CDO wafers at a much faster rate as compared to fumed silica slurries (such as Cu10k-SPF) to give acceptable throughput as shown in FIG. 10. The removal rate can be controlled with the addition of a surfactant. Moreover, in comparison to other materials, CDO films or wafers have a stronger affinity to the surfactant molecules. The resulting coated surface decreases the frictional forces thus reducing material removed, i.e., a lower removal rate as shown in FIG. 11.

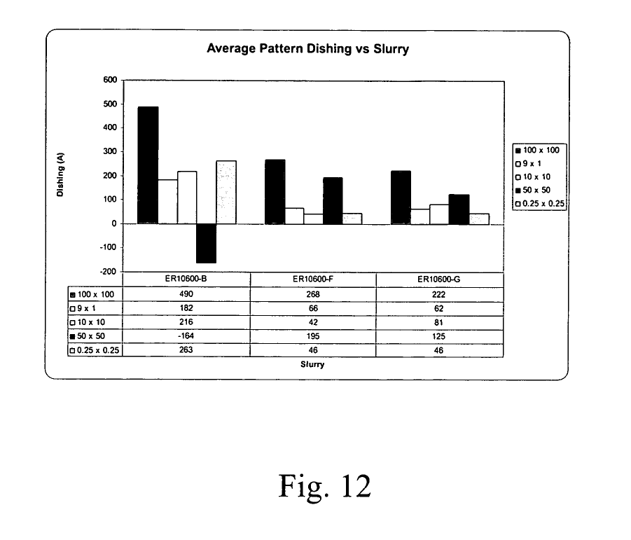

After conventional polish step one (to remove Cu), dishing can range from about 400-800 Å on 100 by 100 micron structures. Post-step dishing, however, can range from 0-400 Å on small dense features, such as 9 by 1 micron structures. FIG. 12 shows that using specific particles within the Sol Gel Colloidal family is critical for optimal topography correction. As used herein, the term topography correction describes how well a barrier slurry or post-step slurry can correct a sample wafer's topography after the conventional first step of polishing. Erosion in the context of the present invention refers to loss in thickness of the supporting material, including oxide and ILD erosion in Cu CMP. Dishing in the context of the present invention refers to the loss in thickness of inlaid material below the surrounding level. Thus, dishing into the copper lines takes place during dual damascene formation.

FIG. 12 further shows the performance of different particles ER10600-B ((below) versus ER10600-F (below) and ER10600-G (below) for the same particles but different silica loading ER10600-F versus ER10600-G. The optimization resulted in the ER10600-G formulation (below). A skilled artisan should note that an incorrect particle type could lead to negative dishing, also referred to as Copper Protrusion. Copper Protrusion itself is known to cause leakage (loss of electrical yield).

ER10600-G

Up to 9% colloidal silica solids
up to 1% carboxylic acid
up to 1% H₂O₂
Alkoxylated surfactant
   ER10600-F
Similar to G except that the silica loading is 6%
   ER10600-B
Similar to ER10600-F, but having different particle shape and size (aggregate)

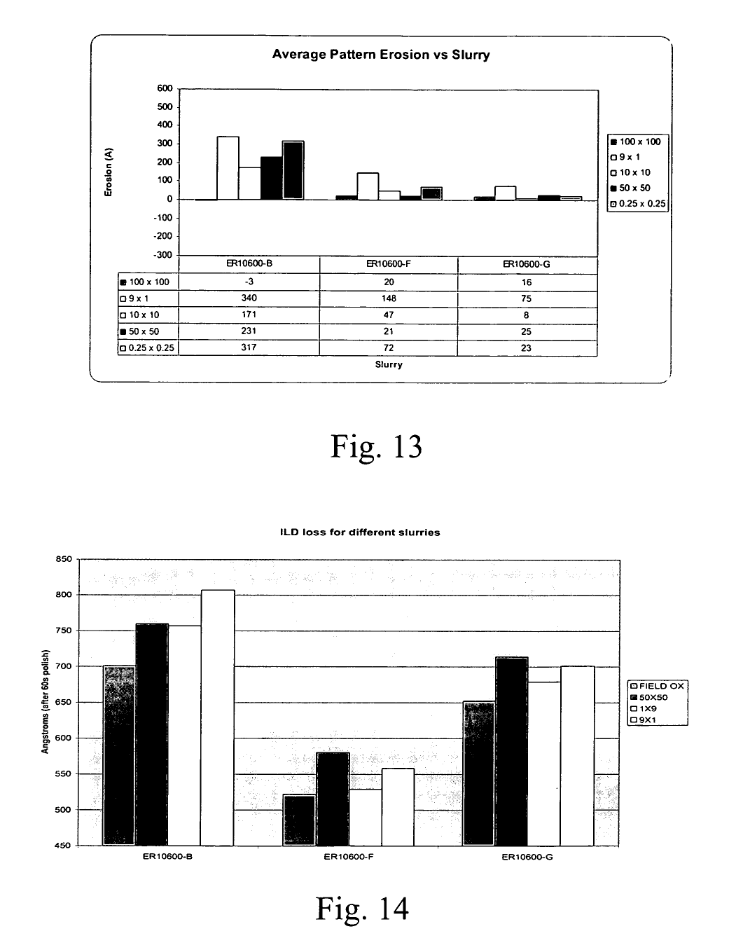

FIG. 13 shows a comparison of an average pattern Erosion for specific types of slurries. For example, there is an observable difference in Erosion between ER 1600-B, ER 1600-F, and ER 1600G slurries. The ILD loss difference between different features is seen in FIG. 14 which shows a better controlled loss for one particular Sol Gel type and loading (ER 10600-G).

Data in FIG. 13 and FIG. 14 was generated on TEOS wafers, and the following were parameters for the polishing process. An AMAT Mirra polisher was used with a Politex pad (manufactured by Rodel Co. Ltd.), a down force (DF) of 2.0 psi, a rotational speed of 97/103 rpm, and a slurry flow of 175 ml/min.

The data shown in FIG. 15 and FIG. 16, indicates that pH is one of the critical parameters to optimize topography correction. The sol gel colloidal silica shows significantly lower erosion compared to other fumed and colloidal particles. The parameters used for the experiment included 854 TEOS wafers, AMAT Mirra polisher with a Politex pad (manufactured by Rodel Co. Ltd.), a down force (DF) of 2.0 psi, a rotational speed of 97/103 rpm, and a slurry flow of 175 ml/min.

Tables 1-5 provide comparative examples of particle shapes in relation to SiO₂ content, Specific Surface Area, Primary and Secondary Particle Size, and Metal Concentration. Each represents an embodiment, which can be selected to for use in a composition for CMP and can be varied to achieve the desired results.

The data reported on Table 1 below, depicts an embodiment of Aggregated-shape particles with a primary particle size of about 15.0 nm; a secondary particle size of about 38.9 nm; an SiO₂ content of about 12.0; a surface area of about 190 m²/g, and a trace metal concentration below 300 ppb. The embodiment has these characteristics and is stable in a neutral pH. An example is shown in FIG. 2.

TABLE 1
Aggregated-Shape Particles

| Test Items | Units | Particle Specifications |
|---|---|---|
| pH | — | 7.1 ± .04 |
| Specific Gravity | — | 1.069 ± .005 |
| SiO₂ Content | wt. % | 12.0 ± 0.3 |
| Specific Surface Area | m2/g | 190 ± 40 |
| Primary Particle Size | nm | 15.0 ± 3.2 |
| Secondary Particle Size | nm | 38.9 ± 7.2 |

| Metals, if present | | Maximum |
|---|---|---|
| Na | ppb | <300 |
| K | ppb | <200 |
| Fe | ppb | <150 |
| Al | ppb | <200 |
| Ca | ppb | <100 |
| Mg | ppb | <100 |
| Ti | ppb | <100 |
| Ni | ppb | <100 |
| Cr | ppb | <100 |
| Cu | ppb | <100 |

The data reported on Table 2 below shows an embodiment of Spherical-shape particles with a primary particle size of about 17.6 nm; a secondary particles size of about 27.6 nm; an SiO₂ content of about 19.5; a surface area of about 159.6 m²/g; and a trace metal concentration below 300 ppb. The embodiment has these characteristics and is stable in a neutral pH. An example of the particles is depicted in FIGS. 2 and 3.

TABLE 2
Spherical-Shape Particles

| Test Items | Units | Particle Specifications |
|---|---|---|
| pH | — | 7.1 ± .04 |
| Specific Gravity | — | 1.120 ± .005 |
| SiO₂ Content | wt. % | 19.5 ± 0.3 |
| Specific Surface Area | m2/g | 159.6 ± 40 |
| Primary Particle Size | nm | 17.6 ± 3.2 |
| Secondary Particle Size | nm | 27.6 ± 7.2 |

| Metals if present | | Maximum |
|---|---|---|
| Na | ppb | <300 |
| K | ppb | <200 |
| Fe | ppb | <150 |
| Al | ppb | <200 |
| Ca | ppb | <200 |
| Mg | ppb | <100 |
| Ti | ppb | <100 |
| Ni | ppb | <100 |
| Cr | ppb | <100 |
| Cu | ppb | <100 |

The data reported on Table 3 below depicts an embodiment of Cocoon-shape particles with a primary particle size of about 23 nm; a secondary particles size of about 50 nm; an SiO₂ content of about 20.0; a surface area of about 125 m²/g, and a trace metal concentration below 300 ppb. The embodiment has these characteristics and is stable in a neutral pH. An example of the particles is depicted in FIG. 4.

TABLE 3
Cocoon-shape particles

| Test Items | Units | Particle Specifications |
|---|---|---|
| pH | — | 7.1 ± .04 |
| Specific Gravity | — | 1.124 ± .005 |
| SiO₂ Content | wt. % | 20.0 ± 0.5 |
| Specific Surface Area | m2/g | 125 ± 30 |
| Primary Particle Size | nm | 23 ± 5 |
| Secondary Particle Size | nm | 38.9 ± 10 |

| Metals if present | | Maximum |
|---|---|---|
| Na | ppb | <300 |
| K | ppb | <200 |
| Fe | ppb | <150 |
| Al | ppb | <200 |
| Ca | ppb | <200 |
| Mg | ppb | <100 |
| Ti | ppb | <100 |
| Ni | ppb | <100 |
| Cr | ppb | <100 |
| Cu | ppb | <100 |

The data reported on Table 3 below depicts another embodiment of an Aggregated-shape particles with a larger primary particle size of about 70 nm, a secondary particles size of about 192 nm, an SiO₂ content of about 23.5; a surface area of about 39.4 m²/g; and a trace metal concentration below 300 ppb. The embodiment has these characteristics and in stable in a neutral pH. An example is depicted in FIG. 5.

TABLE 4
Aggregate-shape particles (Larger Particle Size)

| Test Items | Units | Particle Specifications |
|---|---|---|
| PH | — | 7.1 ± .04 |
| Specific Gravity | — | 1.146 ± .005 |
| SiO₂ Content | wt. % | 23.5 ± 0.3 |
| Specific Surface Area | m2/g | 39.4 ± 3.9 |
| Primary Particle Size | nm | 70.0 ± 7 |
| Secondary Particle Size | nm | 192 ± 7.2 |

| Trace Metals | | Maximum |
|---|---|---|
| Na | ppb | <300 |
| K | ppb | <200 |
| Fe | ppb | <150 |
| Al | ppb | <200 |
| Ca | ppb | <200 |
| Mg | ppb | <100 |
| Ti | ppb | <100 |
| Ni | ppb | <100 |
| Cr | ppb | <100 |
| Cu | ppb | <100 |

The present invention has been described with particular reference to the preferred embodiments. It should be understood that the foregoing descriptions and examples are only illustrative of the invention. Various alternatives and modifications thereof can be devised by those skilled in the art without departing from the spirit and scope of the present invention. Accordingly, the present invention is intended to embrace all such alternatives, modifications, and variations that fall within the scope of the appended claims.

What is claimed is:

1. A composition for chemical mechanical polishing a surface of a substrate comprising:
a plurality of ultra high purity sol gel processed colloidal silica particles having at least one alkali metal selected from a group consisting of: Li, Na, K, Rb, Cs, Fr and a combination thereof, at a total alkali concentration of about 300 ppb or less, with the proviso that the concentration of Na, if present, is about 200 ppb or less; and
a medium for suspending said particles.

2. The composition of claim 1, wherein said alkali metal includes at least one heavy alkali metal selected from a group consisting of: Rb, Cs, Fr, and a mixture thereof, wherein said heavy alkali metal is present at a concentration about 100 ppb or less and wherein the concentration of Na is about 100 ppb or less.

3. The composition of claim 2, wherein said concentration of Na is about 50 ppb or less.

4. The composition of claim 2, wherein said heavy alkali metal is present at a concentration of about 75 ppb or less and wherein the concentration Na is about 50 ppb or less.

5. The composition of claim 2, wherein said heavy alkali metal is present at a concentration of 50 ppb or less.

6. The composition of claim 1, wherein said sol gel silica particles comprise from about 19 wt. % to about 24 wt. % of the total weight of said composition.

7. The composition of claim 1, wherein 0.5% to 49% of said particles have a particle size from about 38 to about 200 nm.

8. The composition of claim 1, wherein at least 50% the particles have a particle size from about 30 nm to about 100 nm.

9. The composition of claim 1, wherein said particles have a particle shape selected from the group consisting of: an aggregated shape, a cocoon shape, and a spherical shape.

10. The composition of claim 1, wherein said particles have a surface area from about 80 m²/g to about 90 m²/g.

11. The composition of claim 1, wherein said particles have a mean particle size from about 60 nm to about 200 nm.

12. The composition of claim 1, wherein said sol gel silica particles have a primary particle size from about 10 nm to about 50 nm and a secondary particle size from about 20 nm to about 150 nm.

13. The composition of claim 1, wherein said particles have a total alkali metal concentration of about 250 ppb or less and wherein the concentration of Na is 100 ppb or less.

14. The composition of claim 1, wherein said particles have a total alkali metal concentration of about 200 ppb or less and wherein the concentration of Na is 50 ppb or less.

15. The composition of claim 1, wherein said particles have a total alkali metal concentration of about 150 ppb or less and wherein the concentration of Na is 50 ppb or less.

16. The composition of claim 1, wherein said particles have a total alkali metal concentration of about 100 ppb or less and wherein the concentration of Na is 50 ppb or less.

17. The composition of claim 17, further comprising a surfactant selected from the group consisting of: anionic, cationic, non-ionic and amphoteric surfactants.

18. The composition of claim 18, wherein said surfactant is an alkoxylated non-ionic surfactant.

19. The composition of claim 17, wherein said surfactant is present in a concentration of about 10 ppm to about 1000 ppm of the total weight of the composition.

20. The composition of claim 1, further comprising an additive selected from the group consisting of: a carboxylic acid and a mixture of carboxylic acids, present in a concentration of about 0.01 wt. % to about 0.9 wt. %; an oxidizer, present in a concentration of about 10 ppm to about 2,500 ppm; a corrosion inhibitor, present in the range of about 10 ppm to about 1000 ppm; and any combinations thereof.

21. The composition of claim 1, wherein said composition is in a form selected from the group consisting of: emulsion, colloidal suspension, solution and slurry.

22. The composition of claim 1, wherein said medium is from about 81 wt. % to about 86 wt. % of the total weight of said composition.

23. The composition of claim 1, wherein said medium is selected from the group consisting of: water, an organic solvent and a mixture thereof.

24. The composition of claim 1, wherein said medium has a pH of about 9.0 to about 11.

25. A method of chemical mechanical polishing a substrate, comprising the step of:
contacting said substrate and a plurality of ultra high purity sol gel processed colloidal silica particles for chemical mechanical polishing having at least one alkali metal selected from a group consisting of: Li, Na, K, Rb, Cs, Fr and a combination thereof, at a total alkali concentration of about 300 ppb or less, with the proviso that the concentration of Na, if present, is less than 200 ppb; and a medium for suspending said particles; wherein said contacting is carried out at a temperature and for a period of time sufficient to planarize said substrate.

26. The method of claim 25, wherein said alkali metals include at least one heavy alkali metal selected from a group consisting of: Rb, Cs, Fr, and a mixture thereof present at a concentration of about 100 ppb or less and wherein the concentration of Na is about 100 ppb or less.

27. The method of claim 26, wherein said heavy metals are present at a concentration of about 100 ppb or less and a Na concentration of about 50 ppb or less.

28. The method of claim 26, wherein said heavy alkali metals are present at a concentration of about 75 ppb or less and a Na concentration of about 50 ppb or less.

29. The method of claim 26, wherein said heavy alkali metals are present at a concentration of about 50 ppb or less.

30. The method of claim 25, wherein said sol gel silica particles comprise from about 19 wt. % to about 24 wt. % of the total weight of said composition.

31. The method of claim 25, wherein said particles have a surface area from about 80 m²/g to about 90 m²/g.

32. The method of claim 25, wherein at least 50% the particles have a particle size from about 30 nm to about 100 nm.

33. The method of claim 25, wherein 0.5% to 49% of said particles have a particle size from about 38 to about 200 nm.

34. The method of claim 25, wherein said particles have a particle shape selected from the group consisting of: an aggregated shape, a cocoon shape, and a spherical shape.

35. The method of claim 25, wherein said particles have an alkali metal concentration of about 250 ppb or less and wherein the concentration of Na is 100 ppb or less.

36. The method of claim 25, wherein said particles have an alkali metal concentration of about 200 ppb or less and wherein the concentration of Na is about 100 ppb or less.

37. The method of claim 25, wherein said particles have an alkali metal concentration of about 150 ppb or less and wherein the concentration of Na is about 50 ppb or less.

38. The method of claim 25, wherein said particles have an alkali metal concentration of about 100 ppb or less and wherein the concentration of Na, if present, is 50 or less.

39. The method of claim 25, further comprising a surfactant selected from the group consisting of: anionic, cationic, non-ionic and amphoteric surfactants and a mixture thereof.

40. The composition of claim 39, wherein said surfactant is an alkoxylated non-ionic surfactant.

41. The method of claim 39, wherein the particles further comprise an additive selected from the group consisting of: a carboxylic acid, present in a concentration of about 0.01 wt. % to about 0.9 wt. %; an oxidizer, present in a concentration of about 10 ppm to about 1000 ppm; a corrosion inhibitor, present in the range of about 10 ppm to about 1000 ppm; and any combinations thereof.

42. The method of claim 25, wherein said composition is in a form selected from the group consisting of: emulsion, colloidal suspension, solution and slurry.

43. The method of claim 25, wherein said medium is from about 81 wt. % to about 86 wt. % of the total weight of said composition.

44. The method of claim 25, wherein said medium has a pH about 6.7 to about 7.6.

45. The method of claim 25, wherein said medium is selected from the group consisting of: water, an organic solvent and a mixture thereof.
